(19) United States
(12) Patent Application Publication
(10) Pub. No.: US 2024/0106544 A1
(43) Pub. Date: Mar. 28, 2024

(54) Optical Transmitter and Method of Calculating an Optical Power

(71) Applicant: Nippon Telegraph and Telephone Corporation, Tokyo (JP)

(72) Inventors: Shigeru Kanazawa, Musashino-shi, Tokyo (JP); Yasuhiko Nakanishi, Musashino-shi, Tokyo (JP); Takahiko Shindo, Musashino-shi, Tokyo (JP); Meishin Chin, Musashino-shi, Tokyo (JP)

(21) Appl. No.: 18/256,390

(22) PCT Filed: Jan. 7, 2021
(86) PCT No.: PCT/JP2021/000321

§ 371 Date: Jun. 7, 2023

(51) Int. Cl. H04B 10/564; H01S 5/028; H01S 5/068; H01S 5/40

(52) U.S. Cl. CPC H04B 10/564; H01S 5/028; H01S 5/068; H01S 5/4087

(57) ABSTRACT

An optical transmitter that multiplexes and outputs a plurality of wavelength channels includes: a first light source; at least one second light source having a different wavelength from the first light source, the at least one second light source each having a different wavelength; an optical multiplexer that causes an output light beam from the first light source to be transmitted from a first end surface to a second end surface facing the first end surface, causes the output light beam from the first light source to be reflected by a reflecting mirror formed on the second end surface, causes an output light beam from the second light source to pass through a wavelength filter formed on the first end surface, causes the optical light beam from the second light source to be reflected by the reflecting mirror, and causes output light beams of the respective wavelength channels to reciprocate between the reflecting mirror and the wavelength filter, to sequentially multiplex the output light beams of the respective wavelength channels.

### TECHNICAL FIELD

The present invention relates to an optical transmitter and an optical power calculation method, and more particularly, to a multi-wavelength channel optical transmitter that uses a wavelength multiplexing optical transmission method, and a method for calculating the optical power of each wavelength channel.

### BACKGROUND ART

With an increase in communication traffic, a wavelength multiplexing optical transmission method is conventionally used to increase the transmission capacity in an optical communication system. To perform wavelength multiplexing optical transmission, light sources are prepared for the respective wavelength channels, and output light beams from a plurality of light sources are multiplexed by an optical multiplexer and are output to an optical fiber. In an optical communication system, it is required to keep the light intensity of an optical transmission signal constant, and, by the wavelength multiplexing optical transmission method, it is also necessary to keep the light intensity of each wavelength channel constant. Therefore, part of the optical transmission signal is split to monitor the light intensity, and the light source is controlled so that the light intensity to be monitored becomes constant.

FIG. 1 illustrates an example of a multi-wavelength channel optical transmitter that is a conventional multi-wavelength channel optical transmitter, and multiplexes four wavelengths. Output light beams from light sources 10a to 10d for the respective wavelength channels are input to an optical multiplexer 20 via collimator lenses 31a to 31d, and are multiplexed. Outputs of the optical multiplexer 20 in all wavelength channels are multiplexed as wavelength multiplexed light via a condenser lens 32, and the wavelength multiplexed light is coupled to an optical fiber 41.

FIG. 2 illustrates an example of a light source. In a light source 10, a light source chip 11 including a modulated light source unit 16 and an optical amplification unit 15 is mounted on a subcarrier 12, and a monitor PD 13 that monitors part of the output light beam from the modulated light source unit 16 is mounted on the rear end of the light source chip 11. The monitor PD 13 detects the optical output power of each wavelength channel as a current value, and a control circuit 14 adjusts the amount of current supply to the light source chip 11 so that the detected current value becomes constant. By such an optical output control (APC) circuit, the optical output power from each light source chip 11 can be made constant at all times (see Non Patent Literature 2, for example).

The optical multiplexer 20 includes a glass block 21, and an antireflective film 22 that transmits an output light beam from the first light source 10a is formed on the end surface on the light source side. A reflecting mirror 24 is formed on the end surface on the output side of the glass block 21, and reflects the output light beam from the first light source 10a toward the light source side. Wavelength filters 23b to 23d that transmit output light beams from the second light sources 10b to 10d and reflect light reflected by the reflecting mirror 24 are formed on the end surface on the light source side. The optical signals of the respective wavelength channels reciprocate between the reflecting mirror 24 and the wavelength filters 23b to 23d, are sequentially multiplexed, pass through an antireflective film 25 formed on the end surface on the output side, and are output as wavelength multiplexed light.

As described above, the configuration in which the monitor PDs 13 are disposed at the rear ends of the light source chips 11 can monitor the optical output power proportional to the output light beams from the light source chips 11. However, the optical output power of each wavelength channel when output as wavelength multiplexed light cannot be accurately monitored.

FIG. 3 illustrates another example of a conventional multi-wavelength channel optical transmitter. Output light beams from light sources 50a to 50d for the respective wavelength channels are input to an optical multiplexer 20 via collimator lenses 31a to 31d and beam splitters 53a to 53d, and are multiplexed. Outputs of the optical multiplexer 20 in all wavelength channels are multiplexed as wavelength multiplexed light via a condenser lens 32, and the wavelength multiplexed light is coupled to an optical fiber 41 (see Non Patent Literature 1, for example).

Output light beams from light source chips 51 are partially split by the beam splitters 53a to 53d, and are monitored by monitor PDs 54a to 54d. Outputs of the monitor PDs 54a to 54d are input to a control circuit for the light sources 50, and the amounts of current supply to the light source chips 51 are adjusted so that the detected current value becomes constant.

As described above, in the configuration in which the monitor PDs 54 are disposed on the output sides of the light source chips 51, outputs from the optical amplification units of the light sources 50 can be accurately monitored, but a light loss equivalent to the passage loss at the beam splitters 53 is generated. Further, the length of the optical path for the output light beam from the first light source 50a to pass through the optical multiplexer 20 is longer than the lengths of the optical paths of the other wavelength channels, and therefore, the loss of the output light beam from the first light source 50a is large.

There also is a method for monitoring the optical output power of each wavelength channel by applying a wavelength filter in place of the reflecting mirror, as in an optical module disclosed in Patent Literature 1. However, preparing individual wavelength filters for the respective wavelength channels leads to increases in cost, such as an increase in the number of components of the optical multiplexer, and an increase in the number of manufacturing steps.

### CITATION LIST

### Patent Literature

Patent Literature 1: JP 2017-98505 A

### Non Patent Literature

Non Patent Literature 1: K. Tsuzuki et. al., “Full C-Band Tunable DFB Laser Array Copackaged With InP Mach-Zehnder Modulator for DWDM Optical Communication Systems,” Journal of selected topics in quantum electronics, vol. 15, no. 3, pp. 521-527, 2009
Non Patent Literature 2: L. B. Aronson et. al., “Transmitter Optical Subassembly for XFP Applications,” ECTC2005, D01:10.1109ECTC.2005.1441402

### SUMMARY OF INVENTION

An embodiment of the present invention is an optical transmitter that multiplexes and outputs a plurality of wavelength channels, and includes: a first light source; at least one second light source having a different wavelength from the first light source, the at least one second light source each having a different wavelength; an optical multiplexer that causes an output light beam from the first light source to be transmitted from a first end surface to a second end surface facing the first end surface, causes the output light beam from the first light source to be reflected by a reflecting mirror formed on the second end surface, causes an output light beam from the second light source to pass through a wavelength filter formed on the first end surface, causes the optical light beam from the second light source to be reflected by the reflecting mirror, and causes output light beams of the respective wavelength channels to reciprocate between the reflecting mirror and the wavelength filter, to sequentially multiplex the output light beams of the respective wavelength channels; a first monitor PD that monitors an optical power, using part of the output light beam from the first light source as reflected light from the optical multiplexer; at least one second monitor PD that monitors an optical power, using part of the output light beam from the second light source as reflected light from the optical multiplexer; and a control circuit that calculates optical powers of the respective output light beams of the first light source and the at least one second light source, from outputs of the first monitor PD and the at least one second monitor PD.

With this configuration, the optical power of each wavelength channel can be calculated without any beam splitter, and thus, a low-loss optical transmitter can be obtained.

### BRIEF DESCRIPTION OF DRAWINGS

FIG. 1 is a diagram illustrating an example of a conventional multi-wavelength channel optical transmitter.

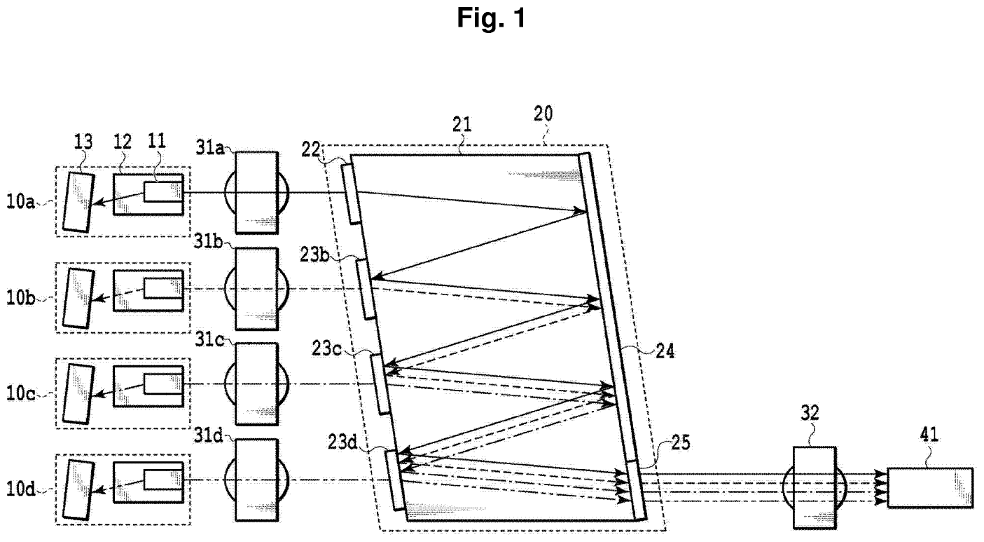

FIG. 2 is a diagram illustrating an example of a light source of the conventional multi-wavelength channel optical transmitter.

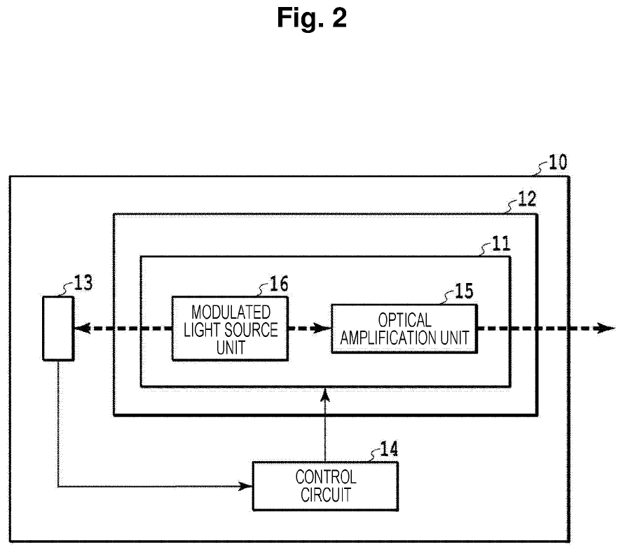

FIG. 3 is a diagram illustrating another example of a conventional multi-wavelength channel optical transmitter.

FIG. 4 is a diagram illustrating a multi-wavelength channel optical transmitter according to Example 1 of the present invention.

FIG. 5 is a diagram illustrating an example of a control circuit of the multi-wavelength channel optical transmitter of Example 1.

FIG. 6 is a diagram illustrating a multi-wavelength channel optical transmitter according to Example 2 of the present invention.

### DESCRIPTION OF EMBODIMENTS

The following is a detailed description of embodiments of the present invention, with reference to the drawings.

### Example 1

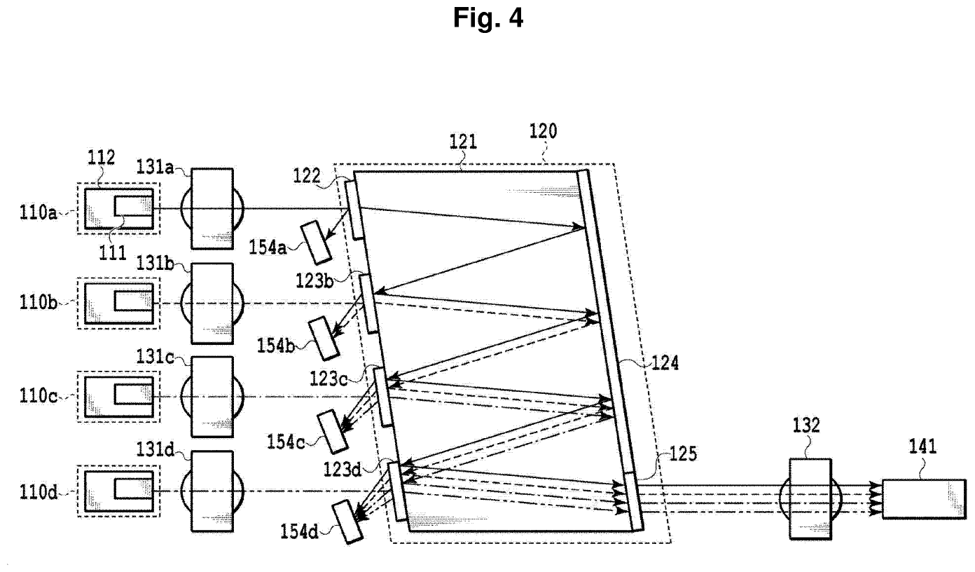

FIG. 4 illustrates an example of a multi-wavelength channel optical transmitter that is a multi-wavelength channel optical transmitter according to Example 1 of the present invention, and multiplexes four different wavelengths. Output light beams from light sources 110a to 110d for the respective wavelength channels are input to an optical multiplexer 120 via collimator lenses 131a to 131d, and are multiplexed. Outputs of the optical multiplexer 120 in all wavelength channels are multiplexed as wavelength multiplexed light via a condenser lens 132, and the wavelength multiplexed light is coupled to an optical fiber 141.

The optical multiplexer 120 includes a glass block 121, and an antireflective film 122 that transmits an output light beam from the first light source 110a is formed on the end surface on the light source side. The antireflective film 122 transmits most optical power, but reflects a small component on the incident side. Therefore, part of the output light beam from the first light source 110a is input as reflected light from the optical multiplexer 120 to a monitor PD 154a, and the optical power of the output light beam from the first light source 110a is monitored. A reflecting mirror 124 is formed on the end surface on the output side of the glass block 121, and reflects the output light beam from the first light source 110a toward the light source side.

Also, wavelength filters 123b to 123d that transmit output light beams from the second light sources 110b to 110d and reflect light reflected by the reflecting mirror 124 are formed on the end surface on the light source side. The wavelength filters 123 transmit most of the optical power with respect to the wavelengths of the output light beams from the second light sources 110b to 110d, but a small component is reflected on the incident side. Further, with respect to the wavelengths of the light beams reflected by the reflecting mirror 124, small components are transmitted to the incident side, despite of the total reflection film. Therefore, part of the output light beams from the second light sources 110b to 110d, and part of the light beams reflected by the reflecting mirror 124 are branched into monitor PDs 154b to 154d. The output light beams from the second light sources 110b to 110d are partially split by the wavelength filters 123b to 123d, and the optical powers of the respective output light beams are monitored by the monitor PDs 154b to 154d. The optical signals of the respective wavelength channels reciprocate between the reflecting mirror 124 and the wavelength filters 123b to 123d, are sequentially multiplexed, pass through an antireflective film 125 formed on the end surface on the output side, and are output as wavelength multiplexed light.

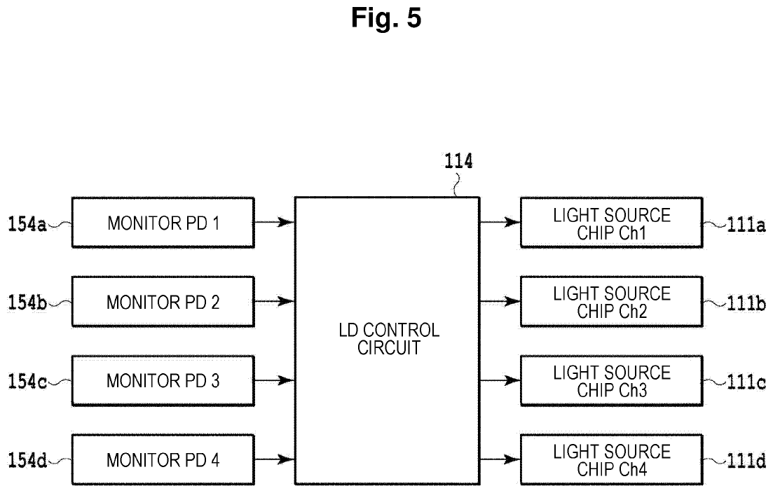

Outputs of the monitor PDs 154a to 154d are input to a control circuit for the light sources 150, and the amounts of current supply to light source chips 151 are adjusted so that the detected current values become constant, or the optical power of each output light beam becomes constant. This aspect will be described later in detail with reference to FIG. 5.

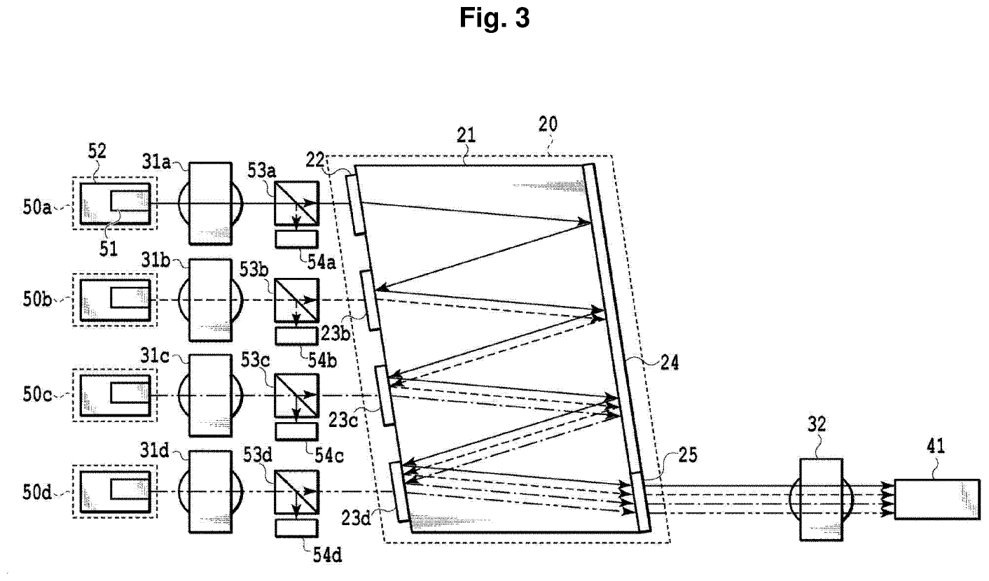

In the conventional optical transmitter illustrated in FIG. 3, the output light beam from the first light source 10 passes through the beam splitter 53 and the antireflective film 22 or the wavelength filter 23 of the optical multiplexer 20, and propagates in the glass block 21. In the optical transmitter of Example 1, on the other hand, the output light beam from the first light source 110 passes only through the antireflective film 122 or the wavelength filter 123 of the optical multiplexer 120, and propagates in the glass block 121. The antireflective film is a unidirectional transmissive film, and can reduce reflection at the end surface of the glass block, but a small reflected component is generated on the incident surface of the antireflective film. As for the wavelength filter, a small reflected component is generated on its incident surface. With the optical transmitter of Example 1, it is possible to accurately monitor optical outputs from the light sources 110 by taking advantage of the reflected components, and form a low-loss optical transmitter in which the light loss due to the beam splitters in the conventional configuration is reduced.

FIG. 5 illustrates an example of a control circuit of the multi-wavelength channel optical transmitter of Example 1. A control circuit 114 detects optical output powers received by the monitor PDs 154a to 154d as current values. The control circuit 114 calculates the optical output powers of the respective wavelength channels from the detected current values, and adjusts the amount of the current supply to light source chips 111 so that the optical output power of each wavelength channel becomes constant.

As illustrated in FIG. 4, only light from the first light source 110a (wavelength channel 1) is input to the monitor PD 154a. In addition to light from the second light source 110b (wavelength channel 2), light from the channel 1 reflected by the reflecting mirror 124 and transmitted through the wavelength filter 123b is also input to the monitor PD 154b. Therefore, it is not possible to immediately determine the optical power of the channel 2 from the optical power detected by the monitor PD 154b. As for the monitors PD 154c and 154d, the light beams in the respective wavelength channels 1 to 4 are sequentially multiplexed, and therefore, the optical power of each individual wavelength channel cannot be determined.

In view of the above, the control circuit 114 calculates the optical power of each wavelength channel through the following procedures. The optical powers input to the monitor PDs 154a to 154d are the values obtained by multiplying the respective reflectances and the respective transmittances of the antireflective films, the reflecting mirror, and the wavelength filters in the paths from the first light source 110 and the second light sources 110b to 110d to the monitor PD 154d. These values are as follows.

[Optical power of monitor PD 154a]=(optical output from first light source 110a)×(reflectance at antireflective film 122)

[Optical power of monitor PD 154b]=(optical output from first light source 110a)×(transmittance at antireflective film 122)×(transmittance from antireflective film 122 to monitor PD 154b)+(optical output from second light source 110b)×(reflectance at wavelength filter 123b)

[Optical power of monitor PD 154c]=(optical output from first light source 110a)×(transmittance at antireflective film 122)×(transmittance from antireflective film 122 to monitor PD 154c)+(optical output from second light source 110b)×(transmittance at wavelength filter 123b)×(transmittance from wavelength filter 123b to monitor PD 154c)+(optical output from second light source 110c)×(reflectance at wavelength filter 123c)

[Optical power of monitor PD 154d]=(optical output from first light source 110a)×(transmittance at antireflective film 122)×(transmittance from antireflective film 122 to monitor PD 154d)+(optical output from second light source 110b)×(transmittance at wavelength filter 123b)×(transmittance from wavelength filter 123b to monitor PD 154d)+(optical output from second light source 110c)×(transmittance at wavelength filter 123c)×(transmittance from wavelength filter 123c to monitor PD 154d)+(optical output from second light source 110d)×(reflectance at wavelength filter 154d)

Step 1 Only the first light source 110a is made to emit light with a known optical power, and the optical power is measured by the monitor PDs 154a to 154d.

[Optical power of monitor PD 154a]=(optical output from first light source 110a)×(reflectance at antireflective film 122=Re1)

[Optical power of monitor PD 154b]=(optical output from first light source 110a)×[(transmittance at antireflective film 122)×(transmittance from antireflective film 122 to monitor PD 154b)=Tr11]

[Optical power of monitor PD 154c]=(optical output from first light source 110a)×[(transmittance at antireflective film 122)×(transmittance from antireflective film 122 to monitor PD 154c)=Tr12]

[Optical power of monitor PD 154d]=(optical output from first light source 110a)×[(transmittance at antireflective film 122)×(transmittance from antireflective film 122 to monitor PD 154d)=Tr13]

Step 2 Likewise, only the second light source 110b is made to emit light, and the respective reflectances and transmittances are calculated from the optical powers detected by the monitor PDs 154b to 154d.

[Optical power of monitor PD 154b]=(optical output from second light source 110b)×(reflectance at wavelength filter 123b=Re2)

[Optical power of monitor PD 154c]=(optical output from second light source 110b)×[(transmittance at wavelength filter 123b)×(transmittance from wavelength filter 123b to monitor PD 154c)=Tr21]

[Optical power of monitor PD 154d]=(optical output from second light source 110b)×[(transmittance at wavelength filter 123b)×(transmittance from wavelength filter 123b to monitor PD 154d)=Tr22]

Step 3 Likewise, only the second light source 110c is made to emit light, and the respective reflectances and transmittances are calculated from the optical powers detected by the monitor PDs 154c and 154d.

[Optical power of monitor PD 154c]=(optical output from second light source 110c)×(reflectance at wavelength filter 123c=Re3)

[Optical power of monitor PD 154d]=(optical output from second light source 110c)×[(transmittance at wavelength filter 123c)×(transmittance from wavelength filter 123c to monitor PD 154d)=Tr31]

Step 4 Likewise, only the second light source 110d is made to emit light, and the reflectance is calculated from the optical power detected by the monitor PD 154d.

[Optical power of monitor PD 154d]=(optical output from second light source 110d)×(reflectance at wavelength filter 154d=Re4)

Step 5 From the measurement results of steps 1 to 4, the respective reflectances (Re) and the respective transmittances (Tr) can be calculated. As described above, the optical powers to be measured in the respective monitor PDs 154a to 154d are as follows.

[Monitor PD 154a]=(optical output from first light source 110a)×Re1

[Monitor PD 154b]=(optical output from first light source 110a)×Tr11+(optical output from second light source 110b)×Re2

[Monitor PD 154c]=(optical output from first light source 110a)×Tr12+(optical output from second light source 110b)×Tr21+(optical output from second light source 110c)×Re3

[Monitor PD 154d]=(optical output from first light source 110a)×Tr13+(optical output from second light source 110b)×Tr22+(optical output from second light source 110c)×Tr31+(optical output from second light source 110d)×Re4

From the calculated reflectances (Re) and the transmittances (Tr), the optical output of the first light source 110a can be calculated, and the optical outputs of the second light sources 110b to 110d can be sequentially calculated. That is, the calculation formulas for calculating the optical outputs from the light sources of the respective wavelength channels are as follows.

(Optical output from first light source 110a)=[optical power of monitor PD 154a]/Re1

(Optical output from second light source 110b)=[[optical power of monitor PD 154b]−(optical output from first light source 110a)×Tr1]/Re2

(Optical output from second light source 110c)=[[optical power of monitor PD 154c]−optical output from first light source 110a)×Tr12−(optical output from second light source 110b)×Tr21]/Re3

(Optical output from second light source 110d)=[[optical power of monitor PD 154d]−(optical output from first light source 110a)×Tr13−(optical output from second light source 110b)×Tr22−(optical output from second light source 110c)×Tr31]/Re4

On the basis of the optical powers calculated according to the calculation formulas, the control circuit 114 adjusts the amounts of current supply to the light source chips 111 so that the optical power of each wavelength channel becomes constant.

With such a configuration, the optical power of each wavelength channel can be calculated without any beam splitter, and thus, a low-loss optical transmitter can be obtained.

After the optical transmitter was assembled as a multi-wavelength channel optical transmitter, the optical output of the optical transmitter was measured through the procedures described above.

Step 1 The optical output of the first light source 110a was set to +4.0 dBm, and optical powers were measured by the monitor PDs 154a to 154d.

[Optical power of monitor PD 154a]=+4.0 dBm×Re1=−13.96 dBm

[Optical power of monitor PD 154b]=+4.0 dBm×Tr11=−14.13 dBm

[Optical power of monitor PD 154c]=+4.0 dBm×Tr12=−14.35 dBm

[Optical power of monitor PD 154d]=+4.0 dBm×Tr13=−14.57 dBm

Step 2 Likewise, the optical output of the second light source 110b was set to +4.0 dBm, and optical powers were measured by the monitor PDs 154b to 154d.

[Optical power of monitor PD 154b]=+4.0 dBm×Re2=−13.96 dBm

[Optical power of monitor PD 154c]=+4.0 dBm×Tr21=−14.13 dBm

[Optical power of monitor PD 154d]=+4.0 dBm×Tr22=−14.35 dBm

Step 3 Likewise, the optical output of the second light source 110c was set to +4.0 dBm, and optical powers were measured by the monitor PDs 154c and 154d.

[Optical power of monitor PD 154c]=+4.0 dBm×Re3=−13.96 dBm

[Optical power of monitor PD 154d]=+4.0 dBm×Tr31=−14.13 dBm.

Step 4 Likewise, the optical output of the second light source 110d was set to +4.0 dBm, and optical power was measured by the monitor PD 154d.

[Optical power of monitor PD 154d]=+4.0 dBm×Re4=−13.96 dBm

Step 5 From the above results, the respective reflectances and transmittances can be expressed as attenuation amounts as follows.

Re1=−17.96 dB

Tr11=−18.13 dB

Tr12=−18.35 dB

Tr13=−18.57 dB

Re2=−17.96 dB

Tr21=−18.13 dB

Tr22=−18.35 dB

Re3=−17.96 dB

Tr31=−18.13 dB

Re4=−17.96 dB

The control circuit 114 holds these attenuation amounts in advance. In actual operation, the control circuit 114 can calculate the optical outputs from the light sources of the respective wavelength channels by substituting the results of measurement performed by the monitor PDs 154a to 154d and the attenuation amounts held in advance into the calculation formulas shown above.

The outputs of the light source chips 111 of the respective wavelength channels were set to +4.0 dBm, and the optical output to be coupled to the optical fiber 141 was measured. In Example 1, the optical outputs of the light sources 110a to 110d of the wavelength channels 1 to 4 were +1.26, +1.43, +1.65, and +1.87 dBm, respectively.

Compared with the conventional optical transmitter illustrated in FIG. 3, the optical outputs of the light sources 10a to 10d of the wavelength channels 1 to 4 were +1.17, +1.34, +1.56, and +1.78 dBm. According to Example 1, it is possible to form a low-loss optical transmitter in which the light loss due to conventional beam splitters is reduced.

### Example 2

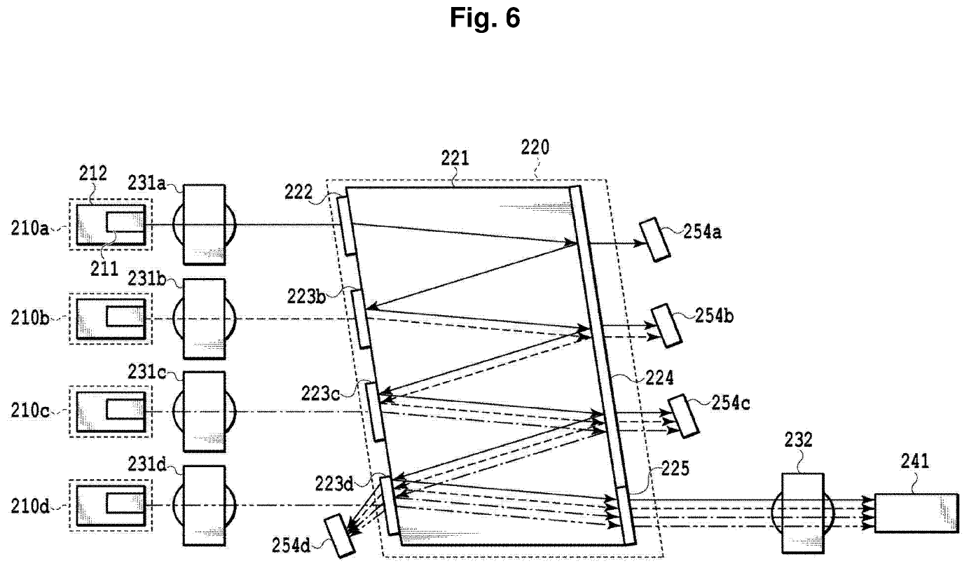

FIG. 6 illustrates a multi-wavelength channel optical transmitter according to Example 2 of the present invention. An example of a multi-wavelength channel optical transmitter that multiplexes four different wavelengths is illustrated. Output light beams from light sources 210a to 210d for the respective wavelength channels are input to an optical multiplexer 220 via collimator lenses 231a to 231d, and are multiplexed. Outputs of the optical multiplexer 220 in all wavelength channels are multiplexed as wavelength multiplexed light via a condenser lens 232, and the wavelength multiplexed light is coupled to an optical fiber 241.

The optical multiplexer 220 includes a glass block 221, and an antireflective film 222 that transmits the output light beam from the first light source 210a is formed on the end surface on the light source side. A reflecting mirror 224 is formed on the end surface on the output side of the glass block 221, and reflects the output light beam from the first light source 210a toward the light source side. The reflecting mirror 224 is a total reflection film, but a small transmitted component is generated. That is, part of the output light beam from the first light source 210a is input as transmitted light from the optical multiplexer 220 to a monitor PD 254a, and the optical power of the output light beam from the first light source 210a is monitored.

Wavelength filters 223b to 223d that transmit output light beams from the second light sources 210b to 210d and reflect light reflected by the reflecting mirror 224 are formed on the end surface on the light source side. The optical signals of the respective wavelength channels reciprocate between the reflecting mirror 224 and the wavelength filters 223b to 223d, are sequentially multiplexed, pass through an antireflective film 225 formed on the end surface on the output side, and are output as wavelength multiplexed light.

Part of the output light beams from the second light sources 210b and 210c passes through the reflecting mirror 224, and is input as transmitted light from the optical multiplexer 220 to monitor PDs 254b and 254c.

Part of the output light beam from the second light source 210d is reflected by the wavelength filter 223d, and is input to a monitor PD 254d.

Outputs of the monitor PDs 254a to 254d are input to a control circuit for the light sources 210, and the amounts of current supply to light source chips 211 are adjusted so that the detected current values become constant, or the optical power of each output light beam becomes constant.

In the conventional optical transmitter illustrated in FIG. 3, the output light beam from the first light source 10 passes through the beam splitter 53 and the antireflective film 22 or the wavelength filter 23 of the optical multiplexer 20, and propagates in the glass block 21. In the optical transmitter of Example 2, on the other hand, the output light beam from the first light source 210 passes only through the antireflective film 222 or the wavelength filter 223 of the optical multiplexer 220, and propagates in the glass block 221. Thus, it is possible to form a low-loss optical transmitter in which the light loss due to conventional beam splitters is reduced.

In the multi-wavelength channel optical transmitter of Example 2, the amounts of current supply to the light source chips 211 are adjusted with the control circuit illustrated in FIG. 5 so that the optical output power of each wavelength channel becomes constant. In view of the above, the control circuit calculates the optical power of each wavelength channel through the following procedures. The optical powers to be input to the monitor PDs 254a to 254d are the values obtained by multiplying the reflectances and the transmittances of the reflective film, the reflecting mirror, and the wavelength filters. These values are as follows.

[Optical power of monitor PD 254a]=(optical output from first light source 210a)×(transmittance at antireflective film 222)×(transmittance from antireflective film 222 to monitor PD 254a)

[Optical power of monitor PD 254b]=(optical output from first light source 210a)×(transmittance at antireflective film 222)×(transmittance from antireflective film 222 to monitor PD 254b)+(optical output from second light source 210b)×(transmittance at wavelength filter 223b)×(transmittance from wavelength filter 223b to monitor PD 254b)

[Optical power of monitor PD 254c]=(optical output from first light source 210a)×(transmittance at antireflective film 222)×(transmittance from antireflective film 222 to monitor PD 254c)+(optical output from second light source 210b)×(transmittance at wavelength filter 223b)×(transmittance from wavelength filter 223b to monitor PD 254c)+(optical output from second light source 210c)×(transmittance at wavelength filter 223c)×(transmittance from wavelength filter 223c to monitor PD 254c)

[Optical power of monitor PD 254d]=(optical output from first light source 210a)×(transmittance at antireflective film 222)×(transmittance from antireflective film 222 to monitor PD 254d)+(optical output from second light source 210b)×(transmittance at wavelength filter 223b)×(transmittance from wavelength filter 223b to monitor PD 254d)+(optical output from second light source 210c)×(transmittance at wavelength filter 223c)×(transmittance from wavelength filter 223c to monitor PD 254d)+(optical output from second light source 210d)×(reflectance at wavelength filter 254d)

After the optical transmitter was assembled as a multi-wavelength channel optical transmitter, the optical output of the optical transmitter was measured in the same manner as in the procedures of Example 1.

Step 1 Only the first light source 210a is made to emit light with an optical power of +5.0 dBm, and the respective reflectances and transmittances are calculated from the optical powers detected by the monitor PDs 254a to 254d.

[Optical power of monitor PD 254a]=(optical output from first light source 210a)×[(transmittance at antireflective film 222)×(transmittance from antireflective film 222 to monitor PD 254a)=Tr11]=+5.0 dBm×Tr11=−11.20 dBm

[Optical power of monitor PD 254b]=(optical output from first light source 210a)×[(transmittance at antireflective film 222)×(transmittance from antireflective film 222 to monitor PD 254b)=Tr12]=+5.0 dBm×Tr12=−11.37 dBm

[Optical power of monitor PD 254c]=(optical output from first light source 210a)×[(transmittance at antireflective film 222)×(transmittance from antireflective film 222 to monitor PD 254c)=Tr13]=+5.0 dBm×Tr13=−11.64 dBm

[Optical power of monitor PD 254d]=(optical output from first light source 210a)×[(transmittance in antireflective film 222)×(transmittance from antireflective film 122 to monitor PD 254d)=Tr14]=+5.0 dBm×Tr14=−11.90 dBm

Step 2 Likewise, only the second light source 210b is made to emit light with the optical power of +5.0 dBm, and the respective reflectances and transmittances are calculated from the optical powers detected by the monitor PDs 254b to 254d.

[Optical power of monitor PD254b]=(optical output from second light source 210b)×[(transmittance at wavelength filter 223b)×(transmittance from wavelength filter 223b to monitor PD254b)=Tr21]=+5.0 dBm×Tr21=−11.20 dBm

[Optical power of monitor PD254c]=(optical output from second light source 210b)×[(transmittance at wavelength filter 223b)×(transmittance from wavelength filter 223b to monitor PD254c)=Tr22]=+5.0 dBm×Tr22=−11.37 dBm

[Optical power of monitor PD254d]=(optical output from second light source 210b)×[(transmittance at wavelength filter 223b)×(transmittance from wavelength filter 223b to monitor PD254d)=Tr23]=+5.0 dBm×Tr23=−11.64 dBm

Step 3 Likewise, only the second light source 210c is made to emit light with the optical power of +5.0 dBm, and the respective reflectances and transmittances are calculated from the optical powers detected by the monitor PDs 254c and 254d.

[Optical power of monitor PD 254c]=(optical output from second light source 210c)×[(transmittance at wavelength filter 223c)×(transmittance from wavelength filter 223c to monitor PD 254c)=Tr31]=+5.0 dBm×Tr31=−11.20 dBm

[Optical power of monitor PD 254d]=(optical output from second light source 210c)×[(transmittance at wavelength filter 223c)×(transmittance from wavelength filter 223c to monitor PD 254d)=Tr32]=+5.0 dBm×Tr32=−11.37 dBm

Step 4 Likewise, only the second light source 210d is made to emit light with the optical power of +5.0 dBm, and the reflectance is calculated from the optical power detected by the monitor PD 254d.

[Optical power of monitor PD 254d]=(optical output from second light source 210d)(reflectance at wavelength filter 254d=Re4)=+5.0 dBm×Re4=−11.20 dBm

Step 5 From the above results, the reflectance and the respective transmittances can be expressed as attenuation amounts as follows.

Tr11=−16.20 dB

Tr12=−16.37 dB

Tr13=−16.64 dB

Tr14=−16.90 dB

Tr21=−16.20 dB

Tr22=−16.37 dB

Tr23=−16.64 dB

Tr31=−16.20 dB

Tr32=−16.37 dB

Re4=−16.20 dB

Holding these attenuation amounts, the control circuit can calculate optical outputs from the light sources of the respective target wavelength channels according to the calculation formulas shown below.

(Optical output from first light source 210a)=[optical power of monitor PD 254a]/Tr11

(Optical output from second light source 210b)=[[optical power of monitor PD 254b]−(optical output from first light source 210a)×Tr12]/Tr21

(Optical output from second light source 210c)=[[optical power of monitor PD 254c]−optical output from first light source 210a)×Tr13−(optical output from second light source 210b)×Tr22]/Tr31

(Optical output from second light source 210d)=[[optical power of monitor PD 254d]−(optical output from first light source 210a)×Tr14−(optical output from second light source 210b)×Tr23−(optical output from second light source 210c)×Tr32]/Re4

The outputs of the light source chips 211 of the respective wavelength channels were set to +5.0 dBm, and the optical output to be coupled to the optical fiber 241 was measured. In Example 2, the optical outputs of the light sources 210a to 210d in the wavelength channels 1 to 4 were +2.12, +2.30, +2.56, and +2.82 dBm, respectively. Compared with the conventional optical transmitter illustrated in FIG. 3, the optical outputs of the light sources 10a to 10d in the wavelength channels 1 to 4 were +1.99, +2.16, +2.42, and +2.69 dBm. According to Example 2, it is possible to form a low-loss optical transmitter in which the light loss due to conventional beam splitters is reduced.

In the examples described above in this embodiment, a multi-wavelength channel optical transmitter multiplexes four wavelengths, the first light source is of the wavelength channel having the longest optical path length for passing light through the optical multiplexer, and the three second light sources are of the other wavelength channels. This embodiment can be applied to any configurations in which the number of second light source is one or larger.

1. An optical transmitter that multiplexes and outputs a plurality of wavelength channels, the optical transmitter comprising:
a first light source;
at least one second light source having a different wavelength from the first light source, the at least one second light source each having a different wavelength;
an optical multiplexer that causes an output light beam from the first light source to be transmitted from a first end surface to a second end surface facing the first end surface, causes the output light beam from the first light source to be reflected by a reflecting mirror formed on the second end surface, causes an output light beam from the second light source to pass through a wavelength filter formed on the first end surface, causes the optical light beam from the second light source to be reflected by the reflecting mirror, and causes output light beams of the respective wavelength channels to reciprocate between the reflecting mirror and the wavelength filter, to sequentially multiplex the output light beams of the respective wavelength channels;
a first monitor PD that monitors an optical power, using part of the output light beam from the first light source as reflected light from the optical multiplexer;
at least one second monitor PD that monitors an optical power, using part of the output light beam from the second light source as reflected light from the optical multiplexer; and
a control circuit that calculates optical powers of the respective output light beams of the first light source and the at least one second light source, from outputs of the first monitor PD and the at least one second monitor PD.

2. The optical transmitter according to claim 1, further comprising an antireflective film that is formed on the first end surface, and splits a reflected component on an incident side into the first monitor PD, the reflected component on the incident side being part of the output light beam from the first light source.

3. The optical transmitter according to claim 1, wherein the wavelength filter splits a reflected component on an incident side into the second monitor PD, the reflected component on the incident side being part of the output light beam from the second light source, and splits a transmitted component toward the incident side into the second monitor PD, the transmitted component toward the incident side being part of light reflected by the reflecting mirror.

4. An optical transmitter that multiplexes and outputs a plurality of wavelength channels, the optical transmitter comprising:
a first light source;
a second light source having a different wavelength from the first light source;
an optical multiplexer that causes an output light beam from the first light source to be transmitted from a first end surface to a second end surface facing the first end surface, causes the output light beam from the first light source to be reflected by a reflecting mirror formed on the second end surface, causes an output light beam from the second light source to pass through a wavelength filter formed on the first end surface, causes the optical light beam from the second light source to be reflected by the reflecting mirror, and causes output light beams of the respective wavelength channels to reciprocate between the reflecting mirror and the wavelength filter, to sequentially multiplex the output light beams of the respective wavelength channels;
a first monitor PD that monitors an optical power of part of the output light beam from the first light source, the output light beam from the first light source having reached the second end surface and passed through the reflecting mirror;
a second monitor PD that monitors an optical power, using part of the output light beam from the second light source as reflected light from the optical multiplexer; and
a control circuit that calculates optical powers of the respective output light beams of the first light source and the second light source, from outputs of the first monitor PD and the second monitor PD.

5. (canceled)

6. The optical transmitter according to claim 4, wherein the wavelength filter splits a reflected component on an incident side into the second monitor PD, the reflected component on the incident side being part of the output light beam from the second light source, and splits a transmitted component toward the incident side into the second monitor PD, the transmitted component toward the incident side being part of light reflected by the reflecting mirror.

7. A method for calculating an optical power of each wavelength channel in an optical transmitter that multiplexes and outputs a plurality of wavelength channels, the optical transmitter including:
a first light source;
at least one second light source having a different wavelength from the first light source, the at least one second light source each having a different wavelength;
an optical multiplexer that causes an output light beam from the first light source to be transmitted from a first end surface to a second end surface facing the first end surface, causes the output light beam from the first light source to be reflected by a reflecting mirror formed on the second end surface, causes an output light beam from the second light source to pass through a wavelength filter formed on the first end surface, causes the optical light beam from the second light source to be reflected by the reflecting mirror, and causes output light beams of the respective wavelength channels to reciprocate between the reflecting mirror and the wavelength filter, to sequentially multiplex the output light beams of the respective wavelength channels;
a first monitor PD that monitors an optical power, using part of the output light beam from the first light source as reflected light from the optical multiplexer; and
at least one second monitor PD that monitors an optical power, using part of the output light beam from the second light source as reflected light from the optical multiplexer,
the method comprising:
a step of calculating reflectances and transmittances of the first light source and the at least one second light source to the second monitor PD that monitors part of the output light beam from the second light source of the wavelength channel to be multiplexed last among the at least one second light source, and holding the reflectances and the transmittances in advance; and
a step of calculating optical powers of the respective output light beams of the first light source and the second light source, from results of measurement performed by the first monitor PD and the at least one second monitor PD, and the reflectances and the transmittances held in advance.

8. The optical transmitter according to claim 2, wherein the wavelength filter splits a reflected component on an incident side into the second monitor PD, the reflected component on the incident side being part of the output light beam from the second light source, and splits a transmitted component toward the incident side into the second monitor PD, the transmitted component toward the incident side being part of light reflected by the reflecting mirror.
